(19) United States
(12) Patent Application Publication
(10) Pub. No.: US 2015/0054011 A1
(43) Pub. Date: Feb. 26, 2015

(54) LIGHT EMITTING DEVICE

(71) Applicant: Kabushiki Kaisha Toshiba, Minato-ku (JP)

(72) Inventors: Hiroshi KOIZUMI, Hiratsuka (JP); Toshihiro KUROKI, Nonoichi (JP); Yasunari UKITA, Kamakura (JP); Tatsuya KOBAYASHI, Yokohama (JP); Keiji NAKAGAWA, Nomi (JP)

(73) Assignee: Kabushiki Kaisha Toshiba, Minato-ku (JP)

(21) Appl. No.: 14/463,933

(22) Filed: Aug. 20, 2014

(30) Foreign Application Priority Data
Aug. 22, 2013 (JP) 2013-172613

(51) Int. Cl. H01L 33/60; H01L 33/50; H01L 33/54

(52) U.S. Cl. CPC H01L 33/60; H01L 33/54; H01L 33/50
USPC 257/98

(57) ABSTRACT

According to one embodiment, a light emitting device includes a base, a light emitting element, a resin layer, a fluorescent material layer, and a lens layer. The base has an under surface, a top surface, and a side surface. The light emitting element is provided on the top surface of the base. The resin layer contacts a side surface of the light emitting element and the top surface of the base. A thickness of the resin layer is thinner from the side surface of the light emitting element toward the side surface of the base. The resin layer has light reflection particle dispersed. The fluorescent material layer is provided on the light emitting element and the resin layer. The lens layer is provided on the base and covers the fluorescent material layer.

### CROSS-REFERENCE TO RELATED APPLICATIONS

This application is based upon and claims the benefit of priority from Japanese Patent Application No. 2013-172613, filed on Aug. 22, 2013; the entire contents of which are incorporated herein by reference.

### FIELD

Embodiments described herein relate generally to a light emitting device.

### BACKGROUND

In a light emitting device based on a light emitting element and a fluorescent material, in general, the light emitting element is provided on a base and the fluorescent material layer is provided on the light emitting element. Mixed color light of light emitted from the light emitting element and light emitted from the fluorescent material layer is emitted from the light emitting device like this.

In the light emitting device like this, it is required that the brightness is further increased. In the light emitting device like this, the chromaticity may change depending on an angle of the light emitted from the light emitting element, namely, so called color breakup phenomena may occur. It is necessary to suppress more the color breakup like this in the light emitting device.

### BRIEF DESCRIPTION OF THE DRAWINGS

FIG. 1A is a schematic side view showing a light emitting device according to a first embodiment, and FIG. 1B is a schematic top view showing the light emitting device according to the first embodiment;

FIG. 2 is a schematic cross-sectional view showing a periphery of a light emitting element of the light emitting device according to the first embodiment;

FIG. 3 is a schematic cross-sectional view showing the operation of a light emitting device according to a reference example;

FIG. 4 is a schematic cross-sectional view showing the operation of the light emitting device according to the first embodiment;

FIG. 5 shows comparison of brightness of the light emitting device according to the first embodiment with brightness of the light emitting device according to the reference example;

FIG. 6 is a schematic cross-sectional view showing a light emitting device according to a variation of the first embodiment;

FIG. 7A is a schematic side view showing a light emitting device according to a second embodiment, and FIG. 7B is a schematic top view showing the light emitting device according to the second embodiment;

FIG. 8A and FIG. 8B show the effect of the second embodiment;

FIG. 9 is a schematic side view showing a light emitting device according to a third embodiment;

FIG. 10A to FIG. 10D are schematic side views showing a part of a manufacturing process of the light emitting device according to the third embodiment; and

FIG. 11 is a schematic side view showing a part of a manufacturing process of a light emitting device according to a variation of the third embodiment.

### DETAILED DESCRIPTION

According to one embodiment, a light emitting device includes a base, a light emitting element, a resin layer, a fluorescent material layer, and a lens layer. The base has an under surface, a top surface, and a side surface. The light emitting element is provided on the top surface of the base. The resin layer contacts a side surface of the light emitting element and the top surface of the base. A thickness of the resin layer is thinner from the side surface of the light emitting element toward the side surface of the base. The resin layer has light reflection particle dispersed. The fluorescent material layer is provided on the light emitting element and the resin layer. The lens layer is provided on the base and covers the fluorescent material layer.

Various embodiments will be described hereinafter with reference to the accompanying drawings. In the following description, the same members are marked with the same numerals, and a detailed description is omitted as appropriate about the members described once.

### First Embodiment

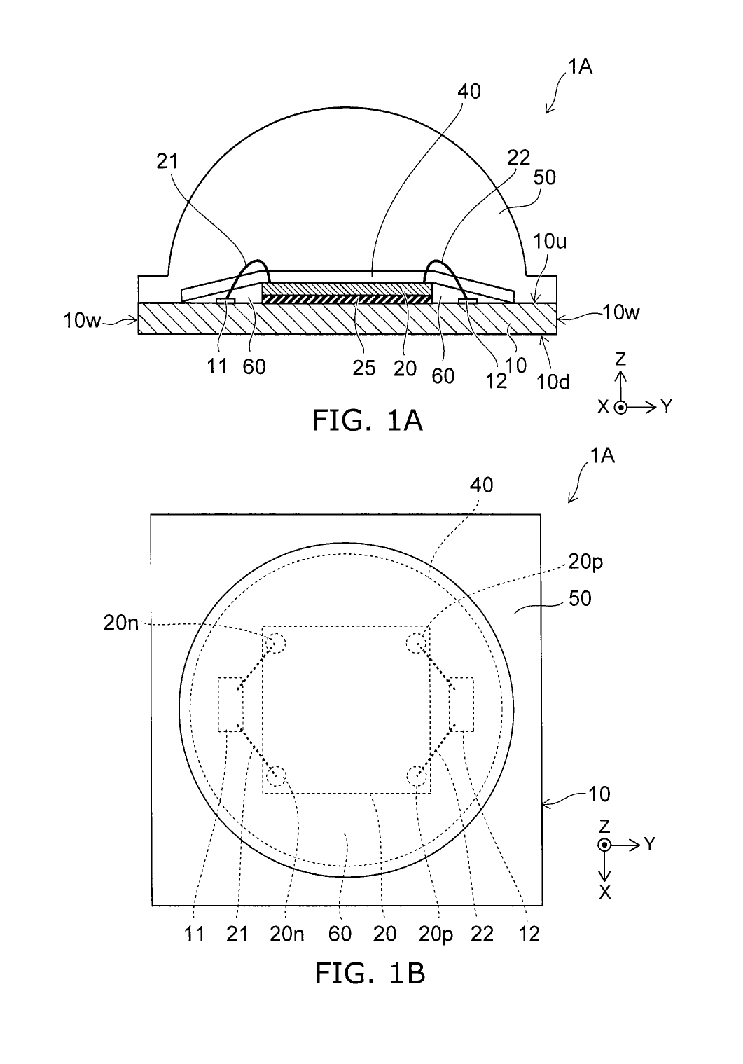

FIG. 1A is a schematic side view showing a light emitting device according to a first embodiment, FIG. 1B is a schematic top view showing the light emitting device according to the first embodiment.

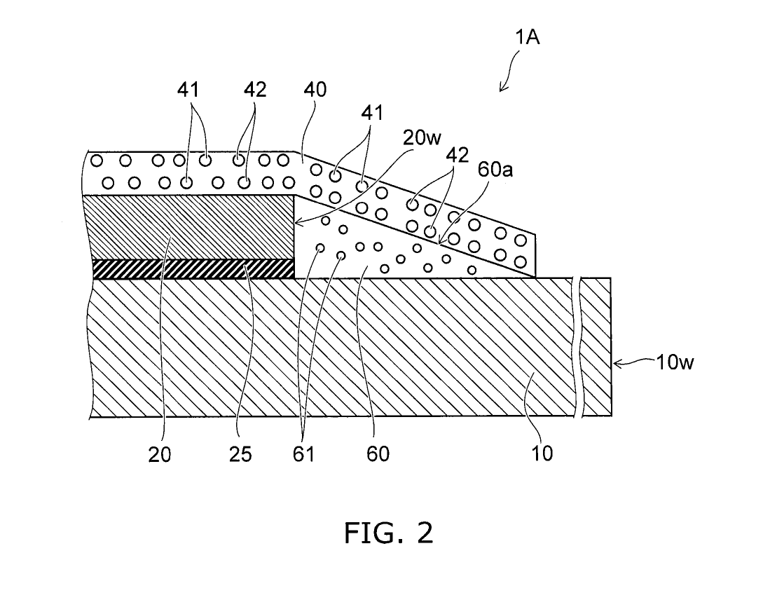

FIG. 2 is a schematic cross-sectional view showing a periphery of a light emitting element of the light emitting device according to the first embodiment.

A light emitting device 1A includes a base 10, a light emitting element 20, a resin layer 60, a fluorescent material layer 40, and a lens layer 50.

The base 10 is a supporting substrate of the light emitting device 1A, and has an under surface 10d and a top surface 10u. The base 10 is, for example, a ceramic plate, a resin plate, and a metal plate or the like.

The light emitting element 20 is provided on the top surface 10u of the base 10 via a bonding layer 25. The light emitting element 20 is, for example, an LED (Light Emitting Diode) of a nitride-based semiconductor. The planar shape of the light emitting element 20 is rectangular. Here, rectangular is taken as square or rectangular.

The light emitting element 20 is able to emit, for example, light in a blue region (440 nm to 470 nm). A p-side electrode 20p and an n-side electrode 20n are disposed at four corners of the light emitting element 20. The light emitting element 20 emits the light mainly in a Z-direction by applying a voltage with a prescribed magnitude between the p-side electrode 20p and the n-side electrode 20n.

The resin layer 60 contacts a side surface 20w of the light emitting element 20 and the top surface 10u of the base 10. A material of the resin layer 60 is, for example, the same as a material of the fluorescent material layer 40. The thickness of the resin layer 60 decreases from the side surface 20w of the light emitting element 20 toward a side surface 10w of the base 10. In other words, the resin layer 60 has a slope 60a where a height of the resin layer decreases from the side surface 20w of the light emitting element 20 toward the side surface 10w of the base 10. A plurality of light reflection particles 61 are dispersed in the resin layer 60.

The light reflection particles 61 are, for example, fine particles including titanium oxide (TiO₂) or zirconium oxide (ZrO₂). An average diameter of the light reflection is, for example, 200 nm to 300 nm. A content rate of the light reflection particles 61 in the resin layer 60 is, for example, 30 to 45 wt %, or 10 vol %.

The fluorescent material layer 40 is provided on the light emitting element 20 and the resin layer 60. A plurality of particulate fluorescent substances are dispersed evenly in the fluorescent material layer 40. In the light emitting device 1A, the fluorescent material layer 40 is provided between the light emitting element 20 and the lens layer 50 and between the resin layer 60 and the lens layer 50. A thickness of the fluorescent material layer 40 is, for example, not more than 50 μm. An average diameter of the fluorescent substances is 50 nm to 1 μm. The fluorescent material layer 40 may be a layer cut from a fluorescent material sheet and may be a layer formed by a coating method.

A material of the fluorescent material layer 40 except the fluorescent substances includes, for example, an epoxy resin, a methacrylic resin (PMMA), polycarbonate (PC), cyclic polyolefin (COF), alicyclic acryl (OZ), a thermoset resin for glass lens (ADC), an acrylic resin, a fluorine-based resin, a silicone-based resin.

Fluorescent substances 41 emitting yellow fluorescence are dispersed in the fluorescent material layer 40. The fluorescent substances 41 is, for example,

Li(Eu,Sm)W₂O₈,

(Y,Gd)₃, (Al,Ga)₅O₁₂:Ce³⁺,

Li₂SrSiO₄:Eu²⁺,

(Sr(Ca,Ba))₃SiO₅:Eu²⁺,

SrSi₂ON_{2.7}:Eu²⁺

or the like.

For example, fluorescent material 42 emitting red fluorescence may be dispersed in the fluorescent material layer 40. The fluorescent substances 42 are, for example,

Y₂O₂S:Eu

Y₂O₂S:Eu+pigment

Y₂O₃:Eu

Zn₃(PO₄)₂:Mn

(Zn,Cd)S:Ag+In₂O₃

(Y,Gd,Eu)BO₃

(Y,Gd,Eu)₂O₃

YVO₄:Eu

La₂O₂S:Eu,Sm

LaSi₃N₅:Eu²⁺

α-sialon:Eu²⁺

CaAlSiN₃:Eu²⁺

CaSiNₓ:Eu²⁺

CaSiNₓ:Ce²⁺

M₂Si₅N₈:Eu²⁺

CaAlSiN₃:Eu²⁺

SrCaSiN:Eu³⁺

(SrCa)AlSiN₃:Eu^{x+}

Srₓ(Si_{y}Al₃)_{z}(OₓN):Eu^{x+}

K₂SiF₆:Mn⁴⁺

or the like.

The light emitting device 1A further includes bonding wires 21, 22.

Each of the bonding wires 21, 22 is, for example, a gold wire, an aluminum wire or the like. The bonding wires 21, 22 are sealed by the lens layer 50 and the resin layer 60.

For example, one end of the bonding wire 21 is connected to the n-side electrode 20n of the light emitting element 20. Other end of the bonding wire 21 is connected to an electrode 11 disposed on the base 10. A portion between the light emitting element 20 and the fluorescent material layer 40 of the bonding wire 21 draws a loop form. The bonding wire 21 connects electrically the light emitting element 20 to the electrode 11.

One end of the bonding wire 22 is connected to the p-side electrode 20p of the light emitting element 20. Other end of the bonding wire 22 is connected to an electrode 12 disposed on the base 10. A portion between the light emitting element 20 and the fluorescent material layer 40 of the bonding wire 22 draws a loop form. The bonding wire 22 connects electrically the light emitting element 20 to the electrode 12.

In the case where the base 10 is a metal plate, an insulating layer is interposed between the electrodes 11, 12 and the metal plate (not shown).

The lens layer 50 is provided on the base 10. A material of the lens layer 50 is, for example, the same as the material of the fluorescent material layer 40. The lens layer 50 covers the light emitting element 20, the fluorescent material layer 40, and the resin layer 60. The lens layer 50 is hemispherical.

A metal film such as a Ag film or the like may be formed on the base 10 in order to assist a light reflection effect on s surface of the base 10 (not shown).

The operation of the light emitting device 1A will be described.

The operation of the light emitting device according to the reference example will be described before describing the operation of the light emitting device 1A.

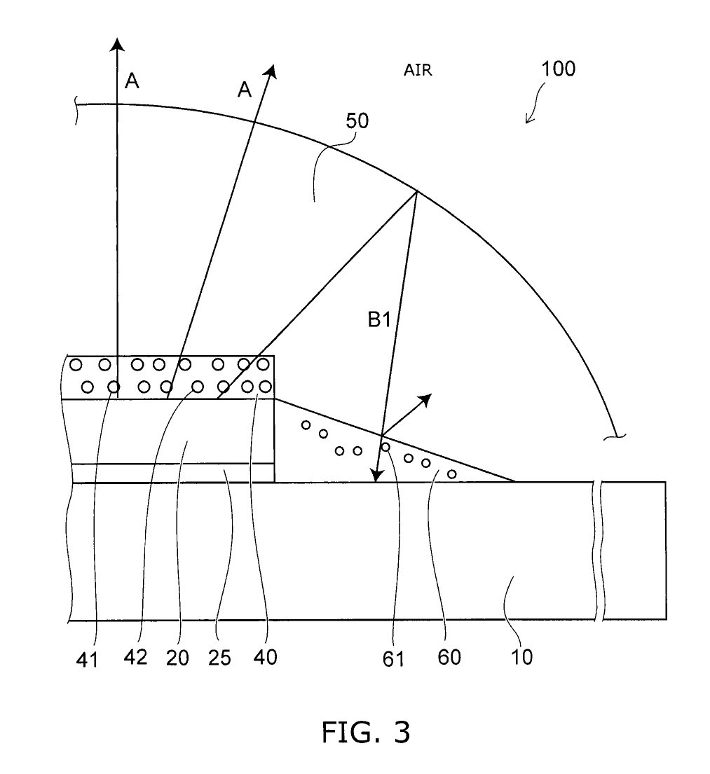

FIG. 3 is a schematic cross-sectional view showing the operation of the light emitting device according to the reference example

In the light emitting device 100 according to the reference example, the fluorescent material layer 40 is not provided on the resin layer 60.

In the light emitting device 100, a part of primary light emitted from the light emitting element 20 is absorbed by the fluorescent material layer 40, and converted into secondary light having a different wavelength from the primary light. Thereby, above the light emitting element 20, the primary light is mixed with the secondary light and mixed light A is obtained. FIG. 3 shows a pathway of the mixed light A by an arrow. Here, in the case where the primary light is blue and the secondary light is yellow, the mixed light A becomes white light obtained by mixing blue with yellow. The primary light of the mixed light A is blue light emitted upward the light emitting element 20. Since the mixed light A is approximately perpendicularly incident on the interface between the lens layer 50 and air, the mixed light A is emitted outside the light emitting device 100 through the interface between the lens layer 50 and air.

On the other hand, some light emitted from the fluorescent layer 40 reflect at the interface between the lens layer 50 and air and return inside the lens layer 50 again. For example, the mixed light including the primary light emitted from the light emitting element 20 at an angle is difficult to be incident perpendicularly to the interface between the lens layer 50 and air, and thus may reflect at the interface between the lens layer 50 and air, and may return inside the lens layer 50. In FIG. 3, this mixed light is taken as “mixed light B1”.

The mixed light B1 is reflected again at the resin layer 60 and travels toward the interface between the resin layer 50 and air, and some mixed light enters into the resin layer 60. The mixed light B1 which enters into the resin layer 60 arrives at the top surface 10u of the base 10, is absorbed by the base 10, repeats reflection at the interface between the lens layer 50 and air and at the interface between the base 10 and the resin layer 60, and decays in time.

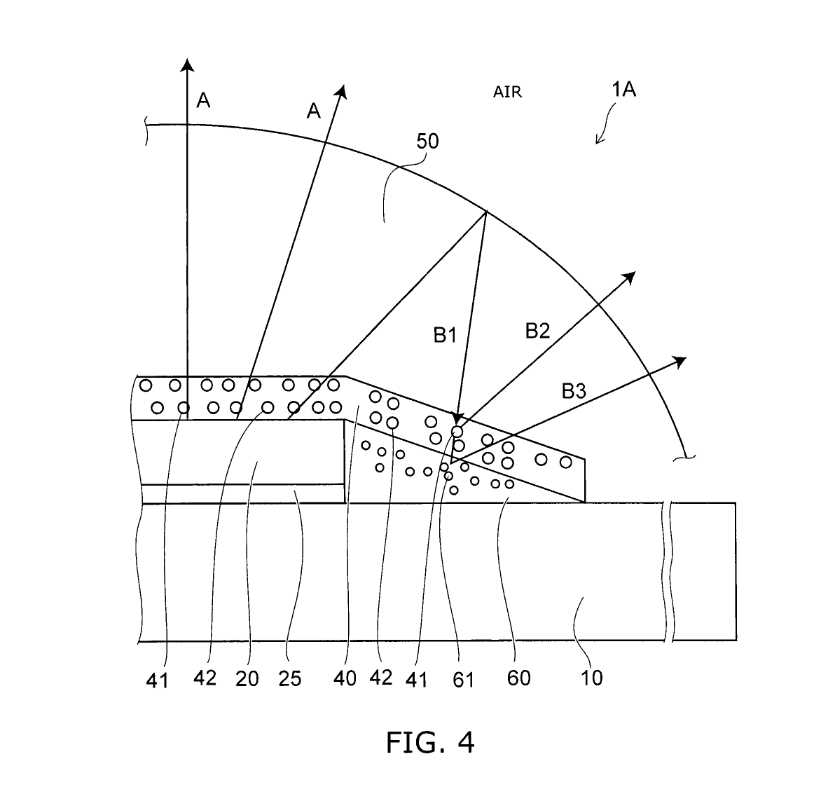

FIG. 4 is a schematic cross-sectional view showing the operation of the light emitting device according to the first embodiment.

In contrast, in the light emitting device 1A according to the first embodiment, the fluorescent material layer 40 is provided on the resin layer 60 dispersed with the light reflection particles 61.

Also in the light emitting device 1A as well as the light emitting device 100, some light reflect at the interface between the lens layer 50 and air and return inside the lens layer 50. In FIG. 4, this mixed light is taken as “mixed light B1”.

However, the mixed light B1 impinges on the fluorescent substances 41 of the fluorescent material layer 40 again, and produces fluorescent color radially. Mixed light B2 and mixed light B3 are shown as one example in FIG. 4 as the produced light. Here, the mixed light B2 is light radiated on a side of the interface between the lens layer 50 and air, and the mixed light B3 is light incident into the resin layer 60.

As described above, in the light emitting device 1A, the light reflection particles 61 are dispersed in the resin layer 60. Thereby, the mixed light B3 incident into the resin layer 60 is reflected by the resin layer 60, and is emitted toward the interface between the lens layer 50 and air and to the outside of the lens layer 50. The mixed light B3 further sometimes impinges on the fluorescent substances to produce the fluorescent color newly.

In other words, in the light emitting device 1A, the mixed light B3 reflected by the resin layer 60 also contributes to brightness of the light emitting device other than the mixed light A, B1, B2. Therefore, the brightness of the light emitting device 1A increases compared with the brightness of the light emitting device 100.

Although FIG. 3, FIG. 4 illustrate a state where the primary light emitted from the light emitting element 20 is irradiated only to the fluorescent substances 41 emitting yellow fluorescence. In practice, the primary light emitted from the light emitting element 20 is irradiated to the fluorescent substances 42 emitting red fluorescence as well, so that the primary light displays blue color and the secondary light displays yellow or red color.

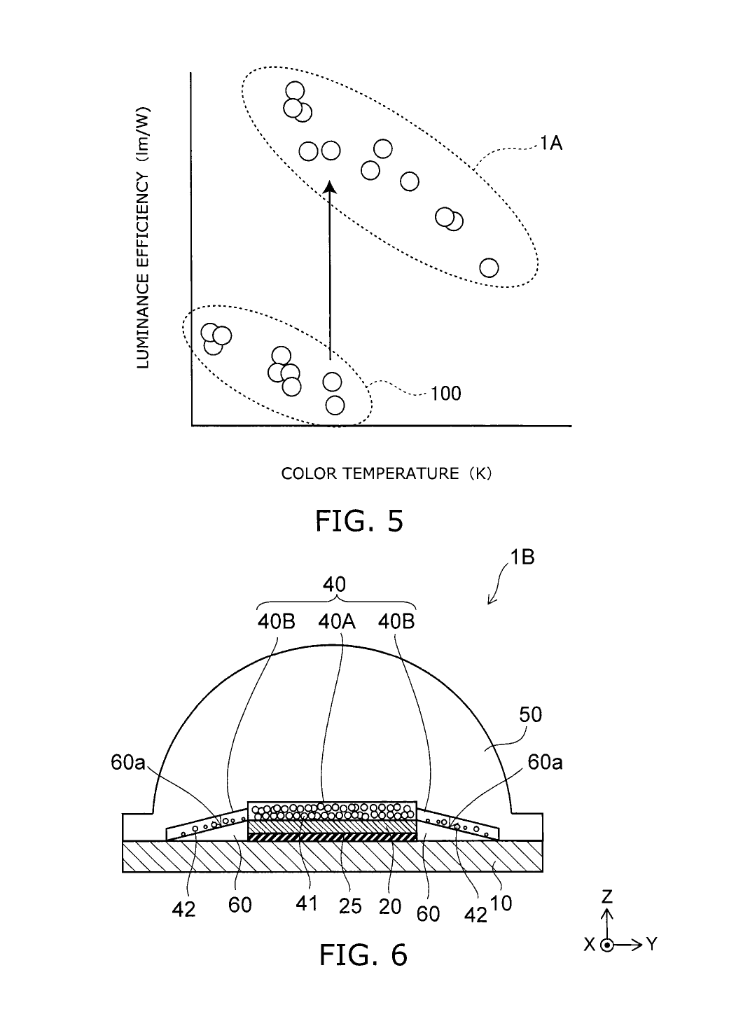

FIG. 5 shows comparison of brightness of the light emitting device according to the first embodiment with brightness of the light emitting device according to the reference example.

The horizontal axis represents color temperature (K), and the vertical axis represents luminance efficiency (Lm/W). Upon manufacturing a plurality of the light emitting devices 1A and a plurality of the light emitting devices 100 experimentally and measuring the relationship between the color temperature (K) and the luminance efficiency (Lm/W), it has been found that the luminance efficiency of the light emitting device 1A is higher than that of the light emitting device 100.

It is particularly preferable that K₂SiF₆:Mn⁴⁺ is used as the fluorescent substance 42 emitting red fluorescence. A wavelength band of K₂SiF₆:Mn⁴⁺ with no absorption of light is broad compared with the fluorescent substance 42 other than K₂SiF₆:Mn⁴⁺. That is, the wavelength band in which K₂SiF₆:Mn⁴⁺ absorbs light shifts to a short wavelength side from the wavelength band in which the fluorescent substance 42 other than K₂SiF₆:Mn⁴⁺. The wavelength band in which K₂SiF₆:Mn⁴⁺ absorbs light overlaps the wavelength band of the light emitting element 20. That is, K₂SiF₆:Mn⁴⁺ absorbs the light emitted from the light emitting element 20 and does not absorb the light of the wavelength band of yellow color shorter than red color, and thus can emit the light of red color.

In general, the light emitted from yellow color-based fluorescent body may be absorbed by red color-based fluorescent body. In order to avoid this, K₂SiF₆:Mn⁴⁺ is used as the red color-based fluorescent substance 42. Thereby, absorption of the light emitted from the blue color-based fluorescent material shorter than red color is suppressed, and the brightness of the light emitting device 1A further increases. Here, K₂SiF₆:Mn⁴⁺ may be applied to light emitting devices illustrated below, not limiting to the light emitting device 1A.

A variation of the first embodiment will be described below.

FIG. 6 is a schematic cross-sectional view showing a light emitting device according to a variation of the first embodiment.

FIG. 6 does not show the electrodes 11, 12 and the bonding wires 21, 22.

A light emitting device 1B includes constituent elements of the light emitting device 1A. However, in the light emitting device 1A, the fluorescent material layer 40 is divided into a first region 40A and a second region 40B. Here, the first region 40A is a region of the fluorescent material layer 40 on the light emitting element 20, and the second region 40B is a region of the fluorescent material layer 40 on the resin layer 60. In other words, the first region 40A is provided between the light emitting element 20 and the lens layer 50, and the second region 40B is provided between the resin layer 60 and the lens layer 50.

In the light emitting device 40B, the fluorescent material included in the first region 40A is different from the fluorescent material included in the second region 40B. For example, the yellow color-based fluorescent substance 41 is dispersed in the first region 40A, and the red color-based fluorescent substance 42 is dispersed in the second region 40 B.

In the light emitting device 1B, the fluorescent material layer 40 is provided on the resin layer 60, and thus the mixed light B3 reflected by the resin layer 60 also contributes to the brightness of the light emitting device other than the mixed light A, B1, B2 as well as the light emitting device 1A. Therefore, the brightness of the light emitting device 1B increases compared with the brightness of the light emitting device 1B.

As described above, in general, light emitted from the yellow color-based fluorescent material may be absorbed by the red color-based fluorescent material. In order to avoid this phenomenon, in the light emitting device 1B, the fluorescent material layer 40 including the yellow color-based fluorescent substance 41 is disposed in a separated region from the fluorescent material layer 40 including the red color-based fluorescent substance 42. Thereby, the light emitted from the yellow color-based fluorescent material becomes hard to be absorbed by the red color-based fluorescent material, and the brightness of the light emitting device 1B increases further compared with the brightness of the light emitting device 1A.

For example, when a refractive index of the light emitting element 20 is 2.0, a refractive index of the fluorescent material layer 40 except the fluorescent substance is 1.9, a refractive index of the resin layer 60 and the lens layer 50 is 1.5, and a refractive index of air is 1.0, the mixed light becomes hard to be reflected at the interface between the fluorescent material layer 40 and the lens layer 50, the interface between the resin layer 60 and the lens layer 50, and the interface between the lens layer 50 and an air layer, and is efficiently emitted to the outside of the light emitting device 1B.

### Second Embodiment

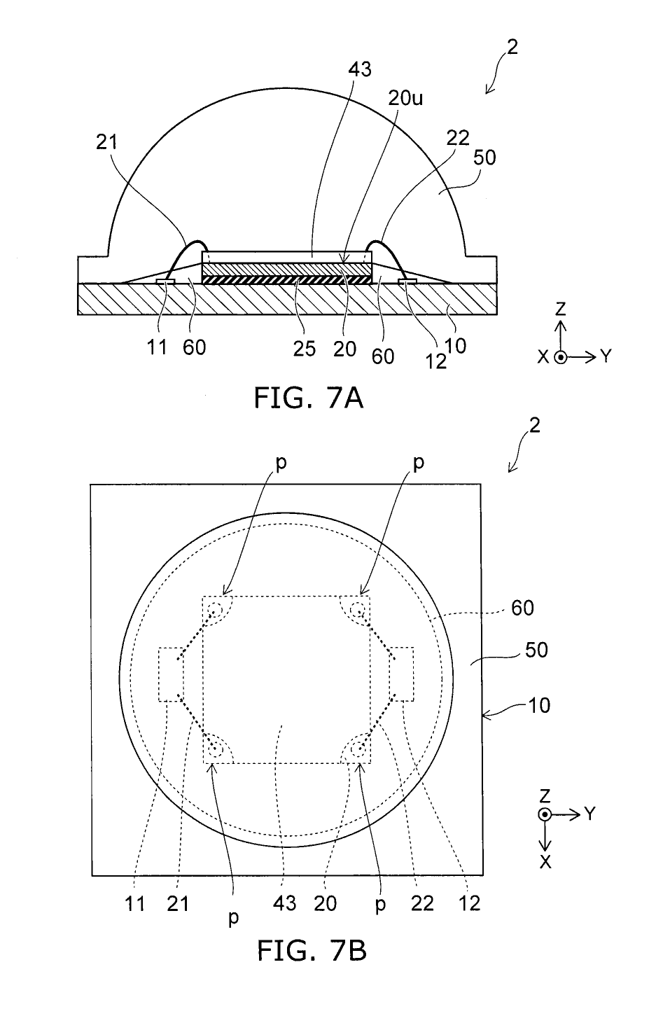

FIG. 7A is a schematic side view showing a light emitting device according to a second embodiment, and FIG. 7B is a schematic top view showing the light emitting device according to the second embodiment.

As shown in FIG. 7A, in the light emitting device 2 according to the second embodiment, the light emitting element 20 is provided on the base 10 via an adhesion layer 25. A fluorescent material layer 43 opening a part of a periphery of the top surface of the light emitting element 20 is provided on the light emitting element 20.

A plurality of particulate fluorescent substances are dispersed evenly in the fluorescent material layer 43. A thickness of the fluorescent material layer 43 is, for example, 50 μm or less. An average diameter of the fluorescent substance is 50 nm to 1 μm.

A material of the fluorescent material layer 40 except the fluorescent substances includes, for example, an epoxy resin, a methacrylic resin (PMMA), polycarbonate (PC), cyclic polyolefin (COF), alicyclic acryl (OZ), a thermoset resin for glass lens (ADC), an acrylic resin, a fluorine-based resin, a silicone-based resin. At least one of the fluorescent substance 41 and the fluorescent substance 42 is dispersed in the fluorescent material layer 43.

The lens layer 50 covering the light emitting element 20, the fluorescent material layer 43, and the resin layer 60 is provided on the base 10. Light reflection particles 61 may be dispersed in the resin layer 60. The resin layer may be appropriately removed in the light emitting device 2.

In the light emitting device 2, as shown in FIG. 7B, the part of the periphery of the top surface 20u of the light emitting element 20 is opened by the fluorescent material layer 43. The opened parts of the top surface 20u of the light emitting element 20 are located at four corners of the rectangular top surface 20u (parts shown by arrows).

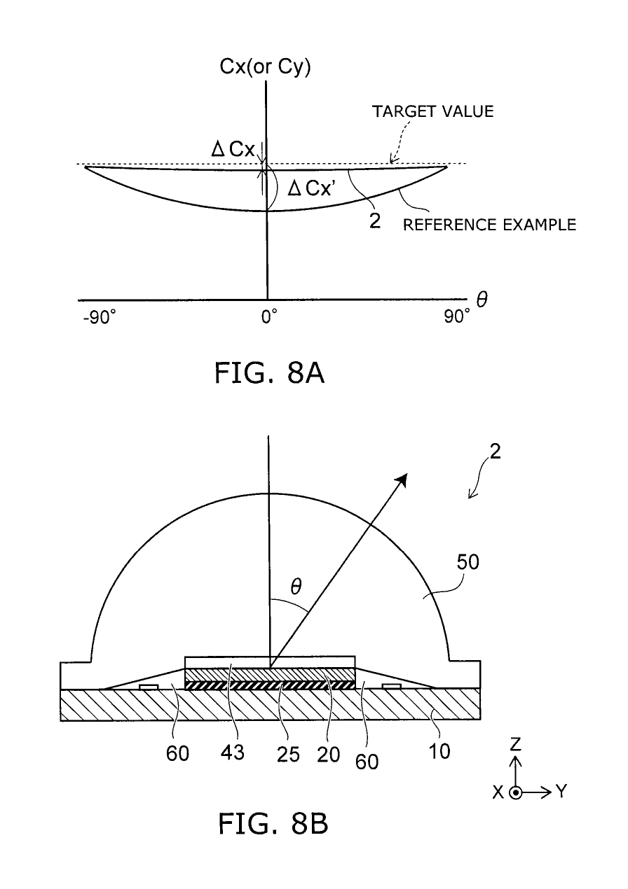

FIG. 8A and FIG. 8B show the effect of the second embodiment.

The horizontal axis of FIG. 8A represents an angle θ of the light emitted from the light emitting element 20, and the vertical axis of FIG. 8B represents chromaticity Cx (normalized value). The chromaticity may be Cy. The angle θ is defined by the angle shown in FIG. 8B. It goes without saying that the light emitted from the light emitting element 20 is not emitted from only one cross point of a normal line and the light emitting element 20 in FIG. 8B, and emitted from the whole area of an active region of the top surface 20u of the light emitting element 20.

FIG. 8A shows the angle dependence of the chromaticity of the light emitting device according to the reference example and the angle dependence of the chromaticity of the light emitting device 2 according to the second embodiment. Here, the light emitting device according to the reference sample is taken as, for example, the light emitting device in which the four corners of the top surface 20u on the light emitting element 20 are not opened from the fluorescent material layer 43 and the whole area of the top surface 20u on the light emitting element 20 is covered with the fluorescent material layer 43. FIG. 8A shows the target value by a broken line. The target value is in a state completely without color breakup (ΔCx=0).

In the light emitting device according to the reference sample, the chromaticity Cx near angle of 0° is lowest, and the chromaticity Cx increases from angle 0° toward angle 90°. This means that blue color is relatively strong near angle 0° and yellow color is relatively strong near angle 90°.

On the other hand, in the light emitting device 2, the four corners of the top surface 20u of the light emitting element 20 are opened from the fluorescent material layer 43. That is, in the light emitting device 2, the primary light emitted from the light emitting element 20 can be preferentially taken from the four corners.

Therefore, in the light emitting device 2, the chromaticity Cx near angle 0° is approximately the same value as the chromaticity Cx near 90°. This means that in angle of −90° to 90°, blue color and yellow color do not place disproportionate emphasis on each other, and both colors are emitted with good balance.

For example, a difference between the chromaticity Cx at angle 0° and the target value is assumed to be ΔCx (light emitting device 2), ΔCx′ (light emitting device according to reference example). ΔCx′ is approximately 0.08 to 0.1, however ΔCx is 0.04 or less.

In the light emitting device 2, the four corners of the top surface 20u on the light emitting element 20 are opened from the fluorescent material layer 43, and thereby the fluorescent material layer 43 is configured not to contact the bonding wires 21, 22. Therefore, even if the bonding wires 21, 22 produce heat, the fluorescent material layer 43 becomes difficult to be influenced by the heat.

Also in the light emitting device 2, the fluorescent material layer may be provided between the resin layer 60 and the lens layer 50. When the fluorescent material layer is provided between the resin layer 60 and the lens layer 50, the fluorescent material layer including the yellow color-based fluorescent substance 41 may be disposed on the light emitting element 20 and the fluorescent material layer including the red color-based fluorescent substance 42 may be disposed on the resin layer 60.

### Third Embodiment

As the light emitting device suppressing the color breakup, a light emitting device described below will be provided other than the light emitting device 2 described above.

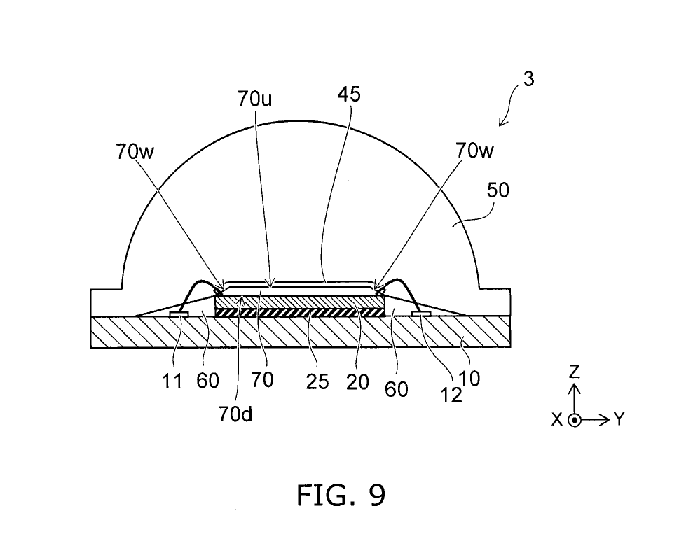

FIG. 9 is a schematic side view showing a light emitting device according to a third embodiment.

In the light emitting device 3 according to the third embodiment, the light emitting element 20 is provided on the base 10. A translucent resin layer 70 is provided on the light emitting element 20. The translucent resin layer 70 has an under surface 70d, a top surface 70u on an opposite side to the under surface 70d, and a side surface 70w crossing the under surface 70d and the top surface 70u. A material of the translucent resin layer 70 is the same as, for example, the material of the lens layer 50. For example, FIG. 9 shows the tapered side surface 70w.

A fluorescent material layer 45 opens a part of the side surface 70w of the translucent resin layer 70, and covers the translucent resin layer 70. Substance of the fluorescent material layer 45, fluorescent substance included in the fluorescent material layer 45 are the same as the substance of the fluorescent material layer 43.

The lens layer 50 is provided on the base 10 and covers the light emitting element 20, the translucent resin layer 70, and the fluorescent material layer 45.

The light emitting device 3 is formed by a manufacturing process described below.

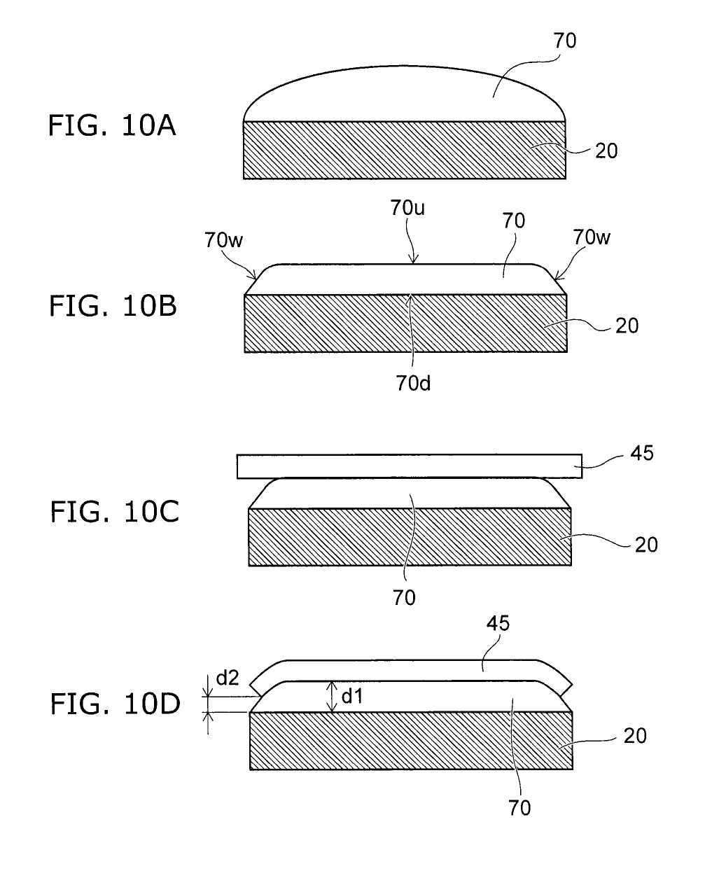

FIG. 10A to FIG. 10D are schematic side views showing a part of a manufacturing process of the light emitting device according to the third embodiment.

First, as shown in FIG. 10A, for example, the translucent resin layer 70 is formed on the light emitting element 20 by a coating method. In this stage, the translucent resin layer 70 is caused to be dissolved in organic solvent in order to lower the viscosity. A surface of the translucent resin layer 70 formed on the light emitting element 20 is a curved surface.

Next, as shown in FIG. 10B, the organic solvent in the translucent resin layer 70 is evaporated by burning. The organic solvent is vaporized from the translucent resin layer 70, and thereby the surface of the translucent resin layer 70 descends and the top surface 70u and the side surface 70w of the translucent resin layer are formed. The side surface 70w crosses the under surface 70d and the top surface 70u.

Next, as shown in FIG. 10C, for example, the sheet form fluorescent material layer 45 cut out into a prescribed shape is disposed on the top surface 70u of the translucent resin layer 70. The fluorescent material layer 45 is based on fluorescent substance having a particle diameter of 1.0 μm or less in order to disperse evenly particulate fluorescent substance. The fluorescent material layer 45 may be formed by the coating method.

Next, as shown in FIG. 10D, the fluorescent material layer 45 is applied to the top surface 70u and a part of the side surface 70w of the translucent resin layer 70 by follow-up burning. The fluorescent material layer 45 is shaped self-aligned along a surface shape of the translucent resin layer 70 by heating.

In the light emitting device 3, for example, the translucent resin layer 70 with a film thickness d1 (for example, 50 μm) is formed between the light emitting element 20 and the fluorescent material layer 45. The structure in which a portion corresponding to a film thickness of d2 of the translucent resin layer 70 on a side of the light emitting element 20 is not covered with the fluorescent material layer 45 is formed. Here, d1 is, for example, 50 μm, and d2 is, for example, 10 μm.

In the structure like this, the portion corresponding to the film thickness d2 of the translucent resin layer 70 is not covered with the fluorescent material layer 45. Therefore, the primary light of the light emitting element 20 can be preferentially taken out from the portion corresponding to the film thickness d2 of the translucent resin layer 70.

Thereby, also in the light emitting device 3, as well as the light emitting device 2, the chromaticity Cx near angle 0° is approximately the same value as the chromaticity Cx near 90°. That is, in angle of −90° to 90°, blue color and yellow color do not place disproportionate emphasis on each other, and both colors are emitted with good balance.

It is preferable to increase the thickness of the translucent resin layer 70 in order to promote a remote phosphor effect (effect of increasing take out of the primary light emitted from the light emitting element 20 by separating the light emitting element 20 from the fluorescent material layer 45) in a light emitting device. However, when increasing the thickness of the translucent resin layer 70, the primary light of the light emitting element 20 leaks too much from the side surface 70w of the translucent resin layer 70, so that the color breakup may be prominent.

In contrast, in the light emitting device 3, even if increasing the thickness of the translucent resin layer 70, since the part of the side surface 70w of the translucent resin layer 70 is covered with the fluorescent material layer 45, the amount of the primary light of the light emitting element 20 leaking from the side surface 70w of the translucent resin layer 70 is appropriately adjusted. That is, in the light emitting device 3, the remote phosphor effect is promoted and the color breakup is suppressed as well.

Also in the light emitting device 3, the fluorescent material layer may be provided between the resin layer 60 and the lens layer 50. When the fluorescent material layer is provided between the resin layer 60 and the lens layer 50, the fluorescent material layer including the yellow color-based fluorescent substance 41 may be disposed on the light emitting element 20 and the fluorescent material layer including the red color-based fluorescent substance 42 may be disposed on the resin layer 60.

The fluorescent material layer 45 covering the part of the side surface 70w of the translucent resin layer 70 cam be formed by a vacuum laminate method.

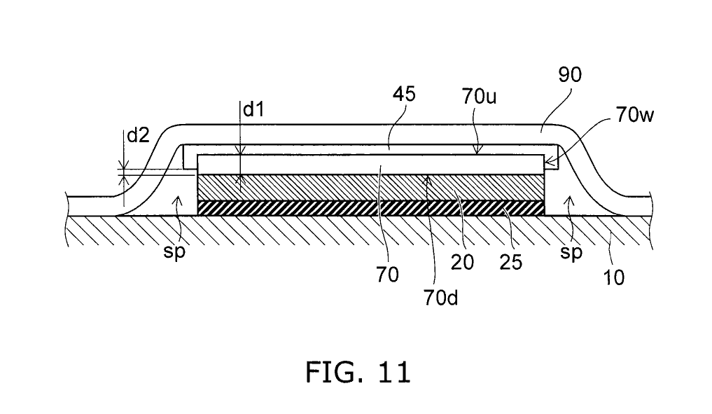

FIG. 11 is a schematic side view showing a part of a manufacturing process of a light emitting device according to a variation of the third embodiment.

For example, the translucent resin layer 70 is formed on the light emitting element 20, and the fluorescent material layer 45 is further placed on the translucent resin layer 70. A sheet 90 is overlaid on the fluorescent material layer 45. When reducing a pressure of atmosphere from this state, the pressure of a space sp surrounded by the sheet 90 and the base 10 is reduced and the fluorescent material layer 45 is pressed toward the translucent resin layer 70 by the sheet 90. The fluorescent material layer 45 is attached onto the top surface 70u of the translucent resin layer 70, and further comes around to the part of the side surface 70w. Such a working example is also included in the embodiment.

In the embodiments described above, “on” in “portion A is provided on portion B” means the case where the portion A contacts the portion B and the portion A is provided on the portion B and the case where the portion A does not contact the portion B and the portion A is provided above the portion B. “Portion A is provided on portion B” may include the case where the portion A and the portion B are reversed and the portion A is located below the portion Band the case where the portion A is arranged along with the portion B. This is because even if rotating semiconductor devices according to embodiments, the structure of the semiconductor devices does not change before and after the rotation.

Although the embodiments are described above with reference to the specific examples, the embodiments are not limited to these specific examples. That is, design modification appropriately made by a person skilled in the art in regard to the embodiments is within the scope of the embodiments to the extent that the features of the embodiments are included. Compositions and the disposition, the material, the condition, the shape, and the size or the like included in the specific examples are not limited to illustrations and can be changed appropriately.

The components included in the embodiments described above can be combined to the extent of technical feasibility and the combinations are included in the scope of the embodiments to the extent that the feature of the embodiments is included. Various other variations and modifications can be conceived by those skilled in the art within the spirit of the invention, and it is understood that such variations and modifications are also encompassed within the scope of the invention.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention.

What is claimed is:

1. A light emitting device comprising:
a base having an under surface, a top surface, and a side surface;
a light emitting element provided on the top surface of the base;
a resin layer contacting a side surface of the light emitting element and the top surface of the base, a thickness of the resin layer being thinner from the side surface of the light emitting element toward the side surface of the base, and the resin layer having light reflection particle dispersed;
a fluorescent material layer provided on the light emitting element and the resin layer; and
a lens layer provided on the base, and the lens covering the fluorescent material layer.

2. The device according to claim 1, wherein the resin layer has a slope.

3. The device according to claim 1, wherein a material of the resin layer is same as a material of the fluorescent material layer except a fluorescent material.

4. The device according to claim 1, wherein the light reflection particle includes an oxide.

5. The device according to claim 1, wherein a material of the lens layer is same as a material of the fluorescent material layer except a fluorescent material.

6. The device according to claim 1, wherein a first fluorescent material included in a first region of the fluorescent material layer on the light emitting element is different from a second fluorescent material included in a second region of the fluorescent material layer on the resin layer.

7. The device according to claim 6, wherein the light emitting element emits blue light, the first fluorescent material emits yellow light, and the second fluorescent material emits red light.

8. The device according to claim 1, wherein refractive indexes of the resin layer and the lens layer are lower than a refractive index of the fluorescent material layer except a fluorescent substance.

9. A light emitting device comprising:
a base;
a light emitting element provided on the base;
a fluorescent material layer provided on the light emitting element, and the fluorescent material layer opening a part of a periphery of a top surface of the light emitting element; and
a lens layer provided on the base, and the lens covering the light emitting element and the fluorescent material layer.

10. The device according to claim 9, wherein
a planar shape of the light emitting element is rectangular, and
the part of the periphery is located at four corners of the rectangle.

11. The device according to claim 9 further comprising:
an electrode provided on the base; and
a bonding wire connecting between the light emitting element and the electrode,
the fluorescent material layer not contacting the bonding wire.

12. The device according to claim 9 further comprising:
a resin layer contacting a side surface of the light emitting element and a top surface of the base, a thickness of the resin layer being thinner from the side surface of the light emitting element toward a side surface of the base, and the resin layer having light reflection particle dispersed.

13. The device according to claim 12, wherein the fluorescent material layer is provided between the resin layer and the lens layer.

14. A light emitting device comprising:
a base;
a light emitting element provided on the base;
a translucent resin layer provided on the light emitting element, and the translucent resin layer having an under surface, a top surface on an opposite side of the under surface, and a side surface crossing the under surface and the top surface;
a fluorescent material layer opening a part of the side surface, and the fluorescent material layer covering the translucent resin layer; and
a lens layer provided on the base, and the lens layer covering the translucent resin layer and the fluorescent material layer.

15. The device according to claim 14 further comprising:
a resin layer contacting a side surface of the light emitting element and a top surface of the base, a thickness of the resin layer being thinner from the side surface of the light emitting element toward a side surface of the base, and the resin layer having light reflection particle dispersed.
